(19) United States
(12) Patent Application Publication
(10) Pub. No.: US 2026/0312580 A1
(43) Pub. Date: Oct. 8, 2026

(54) SEMICONDUCTOR DEVICE

(71) Applicant: FUJI ELECTRIC CO., LTD., Kanagawa (JP)

(72) Inventor: Shigeki SATO, Azumino-city (JP)

(21) Appl. No.: 19/654,485

(22) Filed: Apr. 22, 2026

Related U.S. Application Data
(63) Continuation of application No. PCT/JP2025/014153, filed on Apr. 9, 2025.

(30) Foreign Application Priority Data
May 27, 2024 (JP) 2024-085332

(51) Int. Cl. H03K 17/081; H10D 8/00; H10D 12/00; H10D 84/00; H10D 62/10

(52) U.S. Cl. CPC H03K 17/08116; H10D 8/422; H10D 12/481; H10D 84/161; H10D 62/103

(57) ABSTRACT

A semiconductor device is provided that includes a main transistor portion that causes a main current to flow, and a sense transistor portion that is provided in parallel with the main transistor portion and causes a sense current to flow, wherein a gate resistance ratio obtained by dividing a resistance value of a sense gate resistor, which is a gate drive resistor of the sense transistor portion, by a resistance value of a main gate resistor, which is a gate drive resistor of the main transistor portion, is equal to or greater than 0.015 times a current ratio obtained by dividing the main current by the sense current.

The contents of the following patent application(s) are incorporated herein by reference:

NO. 2024-085332 filed in JP on May 27, 2024

NO. PCT/JP2025/014153 filed in WO on Apr. 9, 2025.

### BACKGROUND

### 1. TECHNICAL FIELD

The present invention relates to a semiconductor device.

### 2. RELATED ART

In a semiconductor device such as an IGBT (Insulated Gate Bipolar Transistor), a configuration is known in which a sense transistor is provided for detecting a current flowing through a main transistor (see, for example, Patent Documents 1 to 3).

Patent Document 1: Japanese Patent Application Publication No. H7-240516

Patent Document 2: Japanese Patent Application Publication No. 2020-14103

Patent Document 3: Japanese Patent Application Publication No. 2019-201349

### BRIEF DESCRIPTION OF THE DRAWINGS

FIG. 1 illustrates an equivalent circuit of the semiconductor device 200 according to one embodiment of the present invention.

FIG. 2 illustrates an example of a time waveform of the emitter voltage Vse of the sense transistor portion 170 when the main transistor portion 70 and the sense transistor portion 170 are turned on.

FIG. 3 illustrates an example of a time waveform of the emitter voltage Vse in the vicinity of a transient period.

FIG. 4 illustrates another example of the time waveform of the emitter voltage Vse in the vicinity of a transient period.

FIG. 5 illustrates another example of the time waveform of the emitter voltage Vse.

FIG. 6 illustrates an example of the waveform of the emitter voltage Vse when absolute values of an area of the main transistor portion 70 and an area of the sense transistor portion 170 are changed with a current ratio (Im/Is) and a gate resistance ratio (Rgs/Rgm) fixed.

FIG. 7 illustrates another example of the waveform of the emitter voltage Vse when absolute values of an area of the main transistor portion 70 and an area of the sense transistor portion 170 are changed with a current ratio (Im/Is) and a gate resistance ratio (Rgs/Rgm) fixed.

FIG. 8 illustrates another configuration example of the semiconductor chip 100.

FIG. 9 illustrates another configuration example of the semiconductor device 200.

FIG. 10 is a diagram for describing another configuration example of the semiconductor device 200.

FIG. 11 is a top view illustrating an example of the semiconductor chip 100.

FIG. 12 illustrates an example of an A-A’ cross section in FIG. 11.

FIG. 13 illustrates an example of the semiconductor device 400 according to a comparative example.

FIG. 14 illustrates another example of the semiconductor device 400 according to the comparative example.

### DESCRIPTION OF EXEMPLARY EMBODIMENTS

The present invention will be described below through embodiments of the invention, but the following embodiments do not limit the invention according to the claims. In addition, not all of the combinations of features described in the embodiments are essential to the solving means of the invention. In the present specification, the same parts in each figure are denoted by the same signs and numerals, and the descriptions thereof may be omitted. In addition, for convenience of description, some configurations may not be illustrated.

As used herein, one side in a direction parallel to a depth direction of a semiconductor substrate is referred to as “upper” and another side is referred to as “lower”. One surface of two principal surfaces of a substrate, a layer or other member is referred to as an upper surface, and another surface is referred to as a lower surface. “Upper” and “lower” directions are not limited to a direction of gravity, or a direction in which a semiconductor device is mounted.

In the present specification, technical matters may be described using an orthogonal coordinate system of an X axis, a Y axis, and a Z axis. The orthogonal coordinate system merely specifies relative positions of components, and does not limit a particular direction. For example, the Z-axis direction is not limited to illustrating a height direction with respect to the ground. Note that a +Z axis direction and a -Z axis direction are directions opposite to each other. When the Z-axis direction is described without describing the signs, it means that the direction is parallel to the +Z axis and the -Z axis.

In the present specification, orthogonal axes parallel to the upper surface and the lower surface of the semiconductor substrate are referred to as the X axis and the Y axis, respectively. In addition, an axis perpendicular to the upper surface and the lower surface of the semiconductor substrate is referred to as the Z axis. In the present specification, the direction of the Z axis may be referred to as a depth direction. In addition, in the present specification, a direction parallel to the upper surface and the lower surface of the semiconductor substrate may be referred to as a horizontal direction, including the X axis and the Y axis.

When a term such as “same” or “equal” is used herein, it may encompass a case where an error due to a variation in manufacturing or the like is included. The error is, for example, within 10%. In addition, in the present specification, the terms "parallel" or "perpendicular" may include an error of within 5°.

In the present specification, a conductivity type of a doping region doped with impurities is described as a P type or an N type. In the present specification, the impurities may particularly mean either donors of the N type or acceptors of the P type and may be described as dopants. In the present specification, doping means introducing the donors or the acceptors into the semiconductor substrate and turning it into a semiconductor presenting a conductivity type of the N type, or a semiconductor presenting a conductivity type of the P type. In the present specification, the doping concentration of the N type region may be referred to as the donor concentration, and the doping concentration of the P type region may be referred to as the acceptor concentration.

In the present specification, a description of a P+ type or an N+ type means a higher doping concentration than that of the P type or the N type, and a description of a P- type or an N- type means a lower doping concentration than that of the P type or the N type. In the present specification, a unit system is the SI base unit system unless otherwise noted.

In the description of a circuit diagram, when arrangement of respective elements is described such as “the third element is provided between the first element and the second element”, the description describes arrangement on an electrical path. That is, the description does not explain spatial relative positions of the first element, the second element, and the third element.

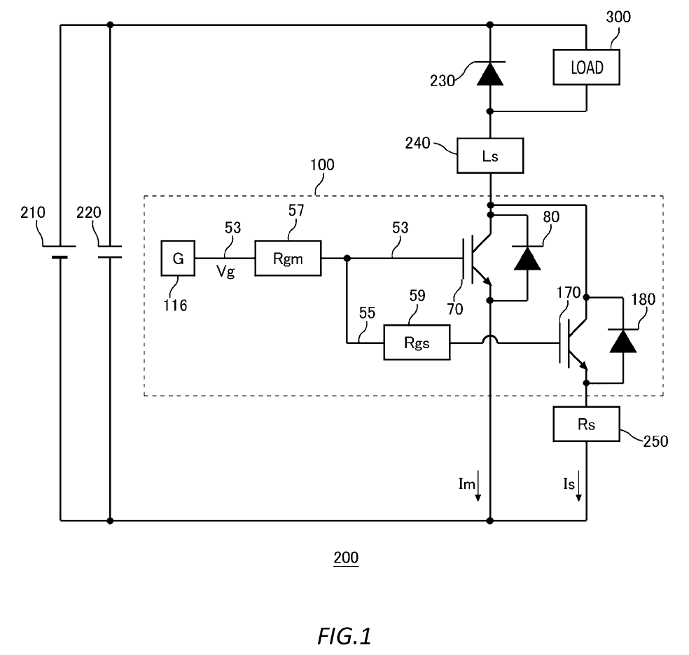

FIG. 1 illustrates an equivalent circuit of the semiconductor device 200 according to one embodiment of the present invention. The semiconductor device 200 controls power supply to the load 300. The semiconductor device 200 includes the semiconductor chip 100. The semiconductor device 200 may include only the semiconductor chip 100, or may be the semiconductor module including the semiconductor chip 100 and a peripheral circuit. The semiconductor module may include the housing that accommodates the semiconductor chip 100 and the peripheral circuit. The housing may include the insulating material such as resin or ceramic.

The semiconductor device 200 may be connected to the external power supply 210. The semiconductor device 200 of this example controls power supply from the external power supply 210 to the load 300.

The semiconductor chip 100 of this example is connected in series with the load 300. The semiconductor chip 100 of this example is the switch that controls whether to interrupt a current flowing through the load 300. The semiconductor chip 100 may be capable of controlling a magnitude of the current flowing through the load 300.

The semiconductor chip 100 includes the main transistor portion 70, the sense transistor portion 170, the main gate resistor 57, and the sense gate resistor 59. The semiconductor chip 100 may further include the gate pad 116 to which the gate signal Vg is applied, the main gate transmission portion 53, and the sense gate transmission portion 55.

The main gate transmission portion 53 is connected to the gate pad 116 and transmits the gate signal Vg to the main transistor portion 70. The main gate transmission portion 53 may include at least one of the metal wiring and the polysilicon wiring provided on the semiconductor substrate.

The sense gate transmission portion 55 is provided in parallel with the main gate transmission portion 53 and transmits the gate signal Vg to the sense transistor portion 170. The sense gate transmission portion 55 may be provided from the gate pad 116 to the sense transistor portion 170, and may be provided by branching from the main gate transmission portion 53 to the sense transistor portion 170.

The main gate resistor 57 is the gate drive resistor of the main transistor portion 70. That is, the main gate resistor 57 is a resistor of the main gate transmission portion 53 from the gate pad 116 to the gate terminal of the main transistor portion 70. When no resistive element is provided in the main gate transmission portion 53, the main gate resistor 57 is the parasitic resistance of the main gate transmission portion 53. The resistance value of the main gate resistor 57 may be, as an example, 10 Ω or less, may be 5 Ω or less, and may be 2 Ω or less. The resistance value of the main gate resistor 57 is greater than 0 Ω.

The sense gate resistor 59 is the gate drive resistor of the sense transistor portion 170. That is, the sense gate resistor 59 is a resistor of the sense gate transmission portion 55 from the gate pad 116 to the gate terminal of the sense transistor portion 170. When the sense gate transmission portion 55 branches from the main gate transmission portion 53, the resistor from the branch point to the gate terminal of the sense transistor portion 170 may be defined as the sense gate resistor 59.

The main transistor portion 70 causes the main current Im to flow in accordance with the applied gate signal Vg. In the example of FIG. 1, the main transistor portion 70 is an IGBT; however, the main transistor portion 70 may be a MOSFET, or may be another transistor. The main transistor portion 70 of this example is provided in series with the load 300. For this reason, the main current Im flowing through the main transistor portion 70 also flows through the load 300. In the example of FIG. 1, the load 300 is connected between the main transistor portion 70 and the external power supply 210.

When the main transistor portion 70 is turned to an off-state in accordance with the gate signal Vg, the current that has been flowing from the load 300 to a reference potential such as a ground potential is interrupted. When the main transistor portion 70 is turned to an on-state in accordance with the gate signal Vg, the predetermined main current Im flows through the load 300.

The semiconductor device 200 may include the freewheeling diode 230 provided in parallel with the load 300. The cathode terminal of the freewheeling diode 230 is connected to the external power supply 210, and the anode terminal of the freewheeling diode 230 is connected to a collector terminal of the main transistor portion 70. When the main transistor portion 70 is turned to an off-state, the current that has been flowing through the load 300 freewheels through the freewheeling diode 230.

The sense transistor portion 170 is provided in parallel with the main transistor portion 70. The sense transistor portion 170 has a structure similar to that of the main transistor portion 70. For example, the sense transistor portion 170 may be a portion obtained by separating, from another region, a part of a region that functions as the main transistor portion 70 in the semiconductor chip 100. The sense transistor portion 170 of this example is an IGBT; however, the sense transistor portion 170 may be a MOSFET, or may be another transistor. The collector terminal of the sense transistor portion 170 is connected to the collector terminal of the main transistor portion 70. The emitter terminal of each of the main transistor portion 70 and the sense transistor portion 170 is connected to the reference potential. However, the sense resistor 250 is provided between the emitter terminal of the sense transistor portion 170 and the reference potential.

The gate signal Vg common to the main transistor portion 70 is applied to the sense transistor portion 170. The sense transistor portion 170 causes the sense current Is to flow in accordance with the applied gate signal Vg. Since the sense transistor portion 170 has a structure similar to that of the main transistor portion 70 and since the gate signal Vg common to the main transistor portion 70 is applied to the sense transistor portion 170, the sense current Is becomes a current proportional to the main current Im. The current ratio between the sense current Is and the main current Im becomes substantially equal to the ratio between the total channel width in the sense transistor portion 170 and the total channel width in the main transistor portion 70. Since the sense transistor portion 170 of this example has a structure similar to that of the main transistor portion 70, the ratio of the total channel widths is determined by the area ratio between the sense transistor portion 170 and the main transistor portion 70, and the current ratio is also determined.

In this specification, the value (Im/Is) obtained by dividing a current value of the main current Im by a current value of the sense current Is is referred to as a current ratio. The current ratio is greater than 1. The current ratio may be 100 or more, may be 1000 or more, or may be 2000 or more. The current ratio of this example is the same as the area ratio obtained by dividing the area occupied by the main transistor portion 70 in the semiconductor substrate by the area occupied by the sense transistor portion 170. The value of the area ratio may be used as the value of the current ratio.

The sense current Is flows through the sense resistor 250. By measuring a voltage between both ends of the sense resistor 250, a magnitude of the sense current Is can be detected. For example, the magnitude of the sense current Is can be calculated by dividing the voltage between both ends of the sense resistor 250 by the resistance value Rs of the sense resistor 250.

The semiconductor chip 100 may include a diode portion 80 connected in anti-parallel with the main transistor portion 70. The semiconductor chip 100 may include a diode portion 180 connected in anti-parallel with the sense transistor portion 170. The diode portion 80 and the diode portion 180 function as freewheeling diodes. The semiconductor chip 100 may be the RC-IGBT (reverse-conducting IGBT). In this example, the cathode terminal of each freewheeling diode portion is connected to the collector terminal of the transistor portion, and the anode terminal is connected to the emitter terminal.

The semiconductor device 200 may further include the capacitor 220. The capacitor 220 is provided in parallel with the external power supply 210. The capacitor 220 can smooth power supplied from the external power supply 210 to the load 300. In addition, FIG. 1 illustrates the stray inductance 240 between the load 300 and the semiconductor chip 100.

When attempting to turn on the main transistor portion 70 and the sense transistor portion 170, the gate dielectric film of each transistor portion may be charged by carriers injected from the collector terminal. Such the phenomenon is referred to as self-charge. When the gate dielectric film is charged by self-charge, the voltage at the gate electrode becomes higher than the voltage of the gate signal Vg. As a result, the transistor portion turns on before the gate signal Vg reaches the threshold voltage. Such the phenomenon is referred to as self-on.

As described above, the area of the sense transistor portion 170 is smaller than the area of the main transistor portion 70. Therefore, the capacitance of the gate dielectric film in the sense transistor portion 170 is relatively small, and the voltage at the gate electrode due to self-charge tends to increase. Therefore, the sense transistor portion 170 may turn on earlier than the main transistor portion 70. When the sense transistor portion 170 turns on first, carriers that should flow to the main transistor portion 70 in the periphery of the sense transistor portion 170 flow to the sense transistor portion 170, and the surge occurs in a time waveform of the sense current Is or the emitter voltage Vse of the sense transistor portion 170.

In the semiconductor device 200, by adjusting the sense gate resistor 59, turn-on of the sense transistor portion 170 is delayed. This suppresses occurrence of a surge in the sense transistor portion 170. More specifically, the gate resistance ratio (Rgs/Rgm) obtained by dividing the resistance value Rgs of the sense gate resistor 59 by the resistance value Rgm of the main gate resistor 57 is adjusted.

The main transistor portion 70 is provided in the predetermined region of the semiconductor substrate. For this reason, gate terminals of the main transistor portion 70 are distributed within the predetermined region. Accordingly, the length of the main gate transmission portion 53 from the gate pad 116 to the gate terminals of the main transistor portion 70 differs depending on a position within the predetermined region, and the magnitude of the resistance of the main gate resistor 57 also differs depending on a position within the predetermined region. When there is variation in the magnitude of the resistance of the main gate resistor 57, the minimum value of the main gate resistor 57 may be used as the resistance value of the main gate resistor 57. In the main gate transmission portion 53 from the gate pad 116 to the gate terminals of the main transistor portion 70, the resistance value of the shortest path may be used as the resistance value of the main gate resistor 57.

The sense gate resistor 59, similarly to the main gate resistor 57, may also have variation depending on the position in the semiconductor substrate. The minimum resistance value of the sense gate resistor 59 may be used as the resistance value of the sense gate resistor 59.

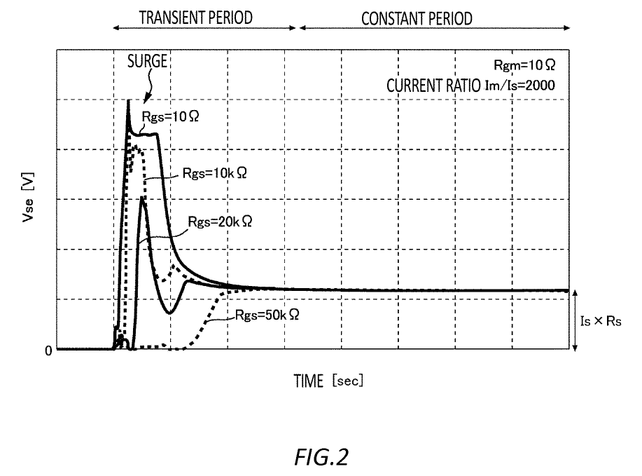

FIG. 2 shows an example of the time waveform of an emitter voltage Vse of the sense transistor portion 170 when the main transistor portion 70 and the sense transistor portion 170 are turned on. In FIG. 2, the emitter voltage of the main transistor portion 70 is set as a reference voltage (0 V). In this example, the resistance value Rgm of the main gate resistor 57 is 10 Ω. In addition, the current ratio Im/Is is 2000. In this specification, when the time waveform of the emitter voltage Vse is shown, unless otherwise specifically described, Rgm=10 Ω and Im/Is=2000.

In FIG. 2, respective waveforms in cases where the resistance values of the sense gate resistor 59 are adjusted to 10 Ω, 10 kΩ, 20 kΩ, and 50 kΩ are shown. The resistance value of the sense gate resistor 59 may be adjusted by inserting the resistive element into the sense gate transmission portion 55. In another example, in at least a part of a section of the sense gate transmission portion 55, a material having a higher resistivity than the main gate transmission portion 53 may be used, the cross-sectional area of wiring may be made smaller than that of the main gate transmission portion 53, and a concentration of impurities implanted into wiring such as polysilicon may be made lower than that of the main gate transmission portion 53.

The emitter voltage Vse of the sense transistor portion 170 converges to a voltage (for example, Is × Rs) corresponding to the sense current Is proportional to the main current Im. A period after the emitter voltage Vse has converged is referred to as the steady period. A period from application of the gate signal Vg of a predetermined on-voltage to the gate terminal of the sense transistor portion 170 until reaching the steady period is referred to as a transient period. In FIG. 2, the transient period and the steady period when the resistance value Rgs of the sense gate resistor 59 is equal to the resistance value Rgm of the main gate resistor 57 (that is, Rgs = Rgm = 10 Ω) are indicated by arrows.

When the resistance value Rgs of the sense gate resistor 59 is equal to the resistance value Rgm of the main gate resistor 57, the sense transistor portion 170 turns on earlier than the main transistor portion 70 due to self-on. As a result, a surge occurs in the emitter voltage Vse in the transient period.

As illustrated in FIG. 2, when the resistance value of the sense gate resistor 59 is increased, the surge in the emitter voltage Vse becomes smaller. In addition, in examples of Rgs = 10 kΩ and 20 kΩ, although the peak of the surge remains, the emitter voltage Vse converges earlier than in the example of Rgs = 10 Ω. In the example of Rgs = 50 kΩ, the surge of the emitter voltage Vse can be removed. Also, the emitter voltage Vse converges faster than in the example of Rgs = 10 Ω.

In the control device of the semiconductor device 200, it is determined whether or not an overcurrent is flowing through the main transistor portion 70 based on the magnitude of the sense current (i.e., the magnitude of the emitter voltage Vse). When the control device determines that an overcurrent is flowing, the control device controls the main transistor portion 70 to be forcibly in the off-state. Thus, the semiconductor device 200 is protected.

On the other hand, the magnitude of the emitter voltage Vse in the transient period does not reflect the magnitude of the main current Im of the main transistor portion 70. Therefore, the control device does not use the emitter voltage Vse in the transient period for detection of the overcurrent. A period during which the emitter voltage Vse is not used for detection of the overcurrent is preset in the control device as the mask period. However, since the overcurrent cannot be detected during the mask period, the semiconductor device 200 cannot be protected. According to this example, by adjusting the resistance value of the sense gate resistor 59, convergence of the emitter voltage Vse can be accelerated. Therefore, the length of the mask period set in the control device can be shortened, and the period during which the semiconductor device 200 can be protected can be expanded.

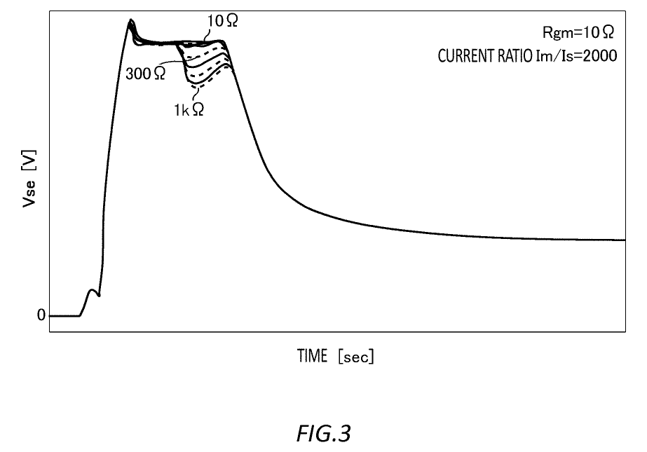

FIG. 3 illustrates an example of the time waveform of the emitter voltage Vse in the vicinity of the transient period. In this example, respective waveforms in cases where the resistance value Rgs of the sense gate resistor 59 is adjusted to 10 Ω, 20 Ω, 40 Ω, 60 Ω, 80 Ω, 100 Ω, 300 Ω, 500 Ω, 700 Ω, 900 Ω, and 1 kΩ are illustrated. In FIG. 3, only waveforms of Rgs = 10 Ω, 300 Ω, and 1 kΩ are indicated, but the larger the resistance value Rgs is, the smaller the surge is.

As illustrated in FIG. 3, when Rgs = 300 Ω, the surge was reduced relatively significantly. The gate resistance ratio (Rgs/Rgm) at this time is 30. Also, the gate resistance ratio (Rgs/Rgm) is 0.015 times the current ratio (Im/Is). Also when the current ratio (Im/Is) is changed, in the example in which the gate resistance ratio (Rgs/Rgm) is set to 0.015 times the current ratio (Im/Is), the surge was reduced relatively significantly. In the semiconductor device 200 of this example, the gate resistance ratio (Rgs/Rgm) is equal to or greater than 0.015 times the current ratio (Im/Is). Thus, as illustrated in FIG. 3, the surge in the emitter voltage Vse can be suppressed. Therefore, erroneous detection of the main current Im can be suppressed. The gate resistance ratio (Rgs/Rgm) may be 30 or more. The resistance value Rgs of the sense gate resistor 59 may be 300 Ω or more.

In this example, the gate resistance ratio (Rgs/Rgm) is adjusted in accordance with the current ratio (Im/Is). Since the current ratio (Im/Is) corresponds to an area ratio of transistor portions, the smaller the area of the sense transistor portion 170 is, the larger the sense gate resistor Rgs is made. As described above, the smaller the area of the sense transistor portion 170 is, the more easily the gate voltage increases due to self-charge. In contrast, by adjusting the gate resistance ratio (Rgs/Rgm) in accordance with the current ratio (Im/Is), the increase in the gate voltage due to self-charge is more easily offset. Therefore, the turn-on timing of the sense transistor portion 170 can be appropriately adjusted.

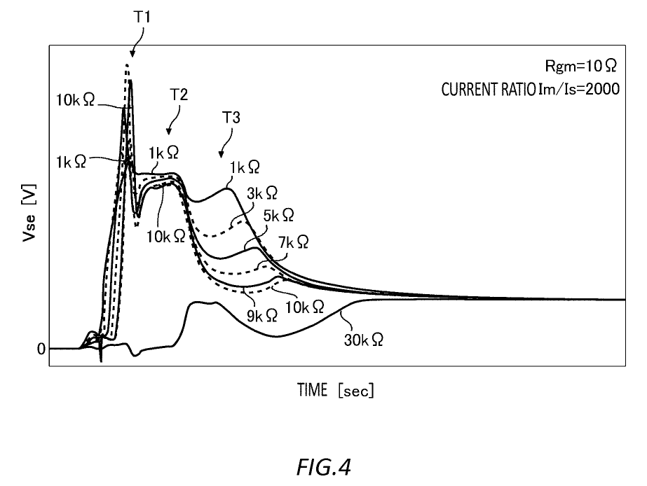

FIG. 4 illustrates another example of a time waveform of the emitter voltage Vse in the vicinity of the transient period. In this example, respective waveforms in cases where the resistance value Rgs of the sense gate resistor 59 is adjusted to 1 kΩ, 3 kΩ, 5 kΩ, 7 kΩ, 9 kΩ, 10 kΩ, and 30 kΩ are illustrated. In the initial period T1 of the transient period, there was a tendency that, when the resistance value Rgs was increased, the instantaneous peak of the surge waveform became larger. In the intermediate period T2 after the initial period T1, there was a tendency that, when the resistance value Rgs was increased, the surge became smaller. In the latter period T3 after the intermediate period T2, when the resistance value Rgs was increased, the surge was significantly reduced.

In particular, when Rgs = 3 kΩ, the surge in the latter period T3 was relatively significantly reduced as compared to the example of Rgs = 1 kΩ. When Rgs = 3 kΩ, the gate resistance ratio (Rgs/Rgm) is 300. Further, the gate resistance ratio (Rgs/Rgm) is 0.15 times the current ratio (Im/Is). In the semiconductor device 200, the gate resistance ratio (Rgs/Rgm) may be equal to or greater than 0.15 times the current ratio (Im/Is). The gate resistance ratio (Rgs/Rgm) may be 300 or more. The resistance value Rgs of the sense gate resistor 59 may be 3 kΩ or more.

When Rgs =9 kΩ, the surge waveform in the latter period T3 became close to flat. Therefore, the mask period set in the control device can be shortened. When Rgs = 9 kΩ, the gate resistance ratio (Rgs/Rgm) is 900. Further, the gate resistance ratio (Rgs/Rgm) is 0.45 times the current ratio (Im/Is). In the semiconductor device 200, the gate resistance ratio (Rgs/Rgm) may be equal to or greater than 0.45 times the current ratio (Im/Is). The gate resistance ratio (Rgs/Rgm) may be 900 or more. The resistance value Rgs of the sense gate resistor 59 may be 9 kΩ or more.

When Rgs = 10 kΩ, the surge waveform in the latter period T3 became substantially flat. Therefore, the mask period set in the control device can be further shortened. When Rgs = 10 kΩ, the gate resistance ratio (Rgs/Rgm) is 1000. Further, the gate resistance ratio (Rgs/Rgm) is 0.5 times the current ratio (Im/Is). In the semiconductor device 200, the gate resistance ratio (Rgs/Rgm) may be equal to or greater than 0.5 times the current ratio (Im/Is). The gate resistance ratio (Rgs/Rgm) may be 1000 or more. The resistance value Rgs of the sense gate resistor 59 may be 10 kΩ or more.

When Rgs = 20 kΩ is set, the gate resistance ratio (Rgs/Rgm) becomes equal to the current ratio (Im/Is). In this case, the turn-on timing of the sense transistor portion 170 and the turn-on timing of the main transistor portion 70 can be made substantially coincident. In this case, as illustrated in FIG. 2, the surge of the emitter voltage Vse becomes considerably small, and the transient period also becomes short.

When the resistance value Rgs is made greater than 20 kΩ, the turn-on timing of the sense transistor portion 170 starts to be delayed relative to the turn-on timing of the main transistor portion 70. However, since the main transistor portion 70 has a larger area than the sense transistor portion 170, even if carriers of the sense transistor portion 170 flow into the main transistor portion 70, there is little influence on the emitter voltage waveform and the like of the main transistor portion 70. Therefore, the resistance value Rgs may be made greater than 20 kΩ.

The gate resistance ratio (Rgs/Rgm) may be equal to or greater than 1 time the current ratio (Im/Is). The gate resistance ratio (Rgs/Rgm) may be 2000 or more. The resistance value Rgs of the sense gate resistor 59 may be 20 kΩ or more.

As illustrated in FIG. 4, when Rgs = 30 kΩ is set, the level of the emitter voltage Vse in the transient period is equal to or below the level of the emitter voltage Vse in the steady period. Therefore, the mask period set in the control device can be made substantially zero. The gate resistance ratio (Rgs/Rgm) may be equal to or greater than 1.5 times the current ratio (Im/Is). The gate resistance ratio (Rgs/Rgm) may be 3000 or more. The resistance value Rgs of the sense gate resistor 59 may be 30 kΩ or more.

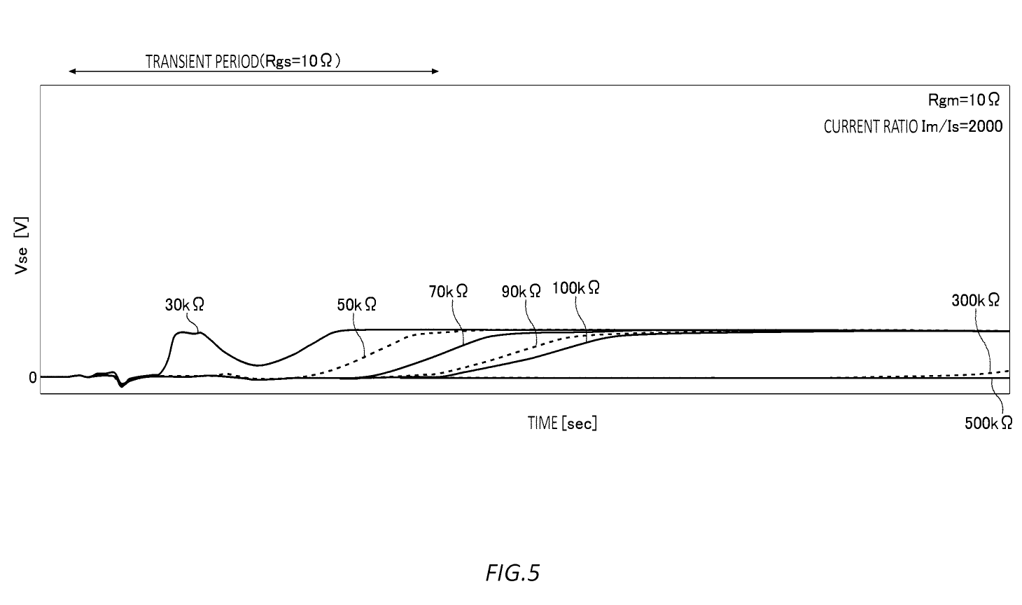

FIG. 5 illustrates another example of the time waveform of the emitter voltage Vse. In this example, respective waveforms in cases where the resistance value Rgs of the sense gate resistor 59 is adjusted to 30 kΩ, 50 kΩ, 70 kΩ, 90 kΩ, 100 kΩ, and 300 kΩ are illustrated. In addition, the transient period in the case of Rgs = 10 Ω is also illustrated together.

As described in FIG. 4, when the resistance value Rgs is set to 30 kΩ or more, the level of the emitter voltage Vse in the transient period can be made equal to or lower than the level of the emitter voltage Vse in the steady period. On the other hand, as the resistance value Rgs is increased, the timing at which the emitter voltage Vse converges to the steady value becomes later.

As illustrated in FIGS. 2 and 5, when Rgs = 50 kΩ, the emitter voltage Vse converges to a steady value within the transient period in the case of Rgs = 10 Ω. Therefore, when Rgs = 50 kΩ, even if the mask period is made shorter than in the case of Rgs = 10 Ω, the steady value of the emitter voltage Vse can be detected with high accuracy. On the other hand, when Rgs = 70 kΩ, the emitter voltage Vse does not converge to a steady value within the transient period in the case of Rgs = 10 Ω. Therefore, the steady value of the emitter voltage Vse cannot be detected with high accuracy unless after the transient period in the case of Rgs = 10 Ω has elapsed. Therefore, the mask period set in the control device cannot be made shorter than in the case of Rgs = 10 Ω.

The gate resistance ratio (Rgs/Rgm) may be equal to or less than 2.5 times the current ratio (Im/Is). The gate resistance ratio (Rgs/Rgm) may be 5000 or less. The resistance value Rgs of the sense gate resistor 59 may be 50 kΩ or less. The gate resistance ratio (Rgs/Rgm) may be equal to or less than 2 times the current ratio (Im/Is). The gate resistance ratio (Rgs/Rgm) may be 4000 or less. The resistance value Rgs of the sense gate resistor 59 may be 40 kΩ or less. The gate resistance ratio (Rgs/Rgm) may be equal to or less than 1.5 times the current ratio (Im/Is). The gate resistance ratio (Rgs/Rgm) may be 3000 or less. The resistance value Rgs of the sense gate resistor 59 may be 30 kΩ or less.

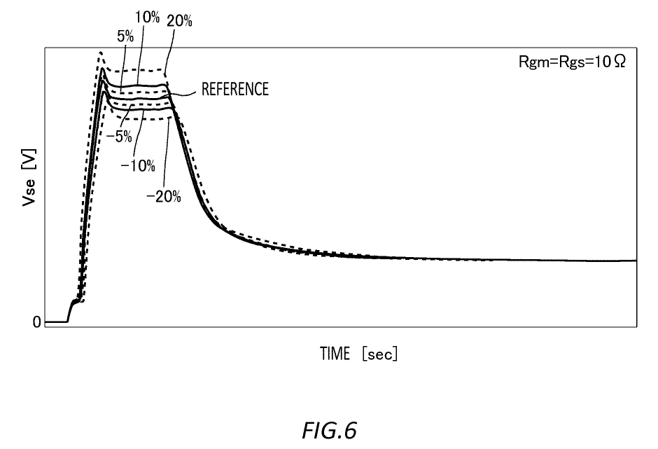

FIG. 6 illustrates an example of waveforms of the emitter voltage Vse when the absolute value of the area of the main transistor portion 70 and the sense transistor portion 170 is changed with the current ratio (Im/Is) and the gate resistance ratio (Rgs/Rgm) fixed. In this example, Rgm = Rgs = 10 Ω. Further, the current ratio (Im/Is) is 2000.

In this example, the absolute values of the area of the main transistor portion 70 and the sense transistor portion 170 were set to a reference value, the reference value +5% (that is, the reference value ×1.05), the reference value +10%, the reference value +20%, the reference value -5%, the reference value -10%, and the reference value -20%. Although the emitter voltage Vse tends to be higher as the areas of the main transistor portion 70 and the sense transistor portion 170 are larger, the length of the transient period hardly changes. Further, the magnitude of the emitter voltage Vse per unit area, which is obtained by dividing the magnitude of the emitter voltage Vse by the area of the sense transistor portion 170, is substantially unchanged.

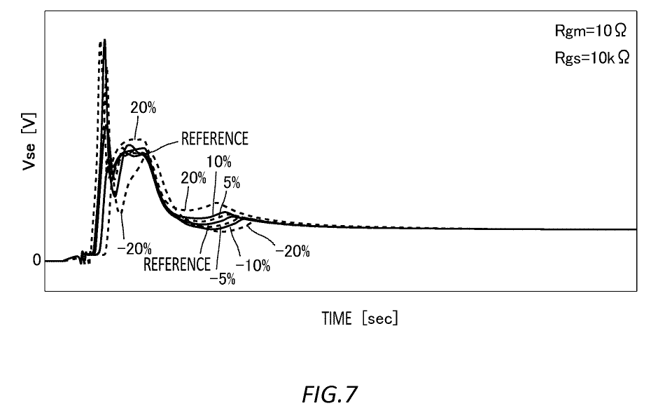

FIG. 7 illustrates another example of waveforms of the emitter voltage Vse when the absolute value of the areas of the main transistor portion 70 and the sense transistor portion 170 is changed with the current ratio (Im/Is) and the gate resistance ratio (Rgs/Rgm) fixed. In this example, conditions other than Rgs = 10 kΩ are similar to those in the example of FIG. 6. Also in this example, the tendency similar to that in the example of FIG. 6 was observed.

As illustrated in FIGS. 6 and 7, even when the absolute value of the areas of the main transistor portion 70 and the sense transistor portion 170 is changed, the magnitude of the surge of the emitter voltage Vse and the period until convergence are not improved very much. On the other hand, as described in FIGS. 1 to 5, by adjusting the gate resistance ratio (Rgs/Rgm) in accordance with the current ratio (Im/Is), at least one of the magnitude of the surge of the emitter voltage Vse and the period until convergence can be improved.

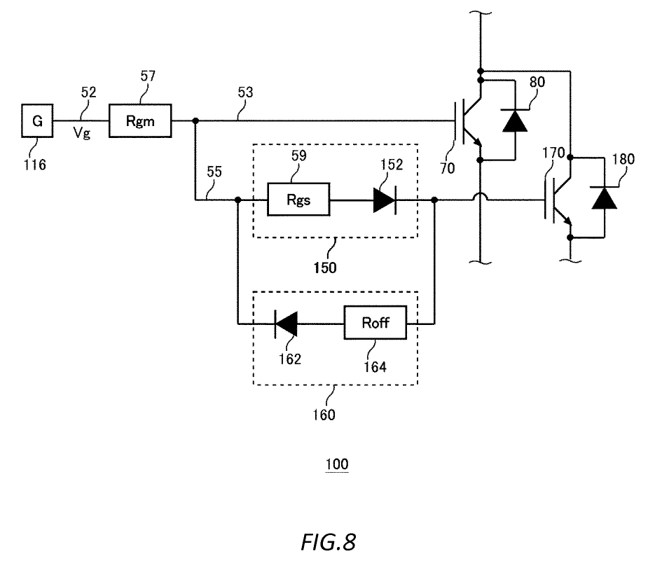

FIG. 8 illustrates another configuration example of the semiconductor chip 100. The sense gate transmission portion 55 of the semiconductor chip 100 of this example has the on path 150 and the off path 160. The on path 150 has the sense gate resistor 59, and causes a gate current to flow to the gate terminal of the sense transistor portion 170 in accordance with the gate signal Vg.

The on path 150 of this example includes the sense gate resistor 59 and the first diode 152. In the first diode 152, the cathode terminal is connected to the gate terminal of the sense transistor portion 170. The sense gate resistor 59 is provided in series with the first diode 152. In the example of FIG. 8, the first diode 152 is provided between the sense gate resistor 59 and the sense transistor portion 170. In another example, the sense gate resistor 59 may be provided between the first diode 152 and the sense transistor portion 170. With such a configuration, the on path 150 allows a current for charging the gate capacitance of the sense transistor portion 170 to flow, and does not allow a current for discharging to flow. For this reason, the sense gate resistor 59 functions as a gate resistor when charging the gate capacitance of the sense transistor portion 170.

The off path 160 is provided in parallel with the on path 150, and extracts charge from the gate terminal of the sense transistor portion 170 in accordance with the gate signal Vg. The off path 160 of this example includes the sense-off resistor 164 and the second diode 162. In the second diode 162, the anode terminal is connected to the gate terminal of the sense transistor portion 170. The sense-off resistor 164 is provided in series with the second diode 162. In the example of FIG. 8, the sense-off resistor 164 is provided between the second diode 162 and the sense transistor portion 170. In another example, the second diode 162 may be provided between the sense-off resistor 164 and the sense transistor portion 170. With such a configuration, the off path 160 allows the current for discharging charge of the gate capacitance of the sense transistor portion 170 to flow, and does not allow the current for charging to flow. For this reason, the sense-off resistor 164 functions as the gate resistor when discharging the gate capacitance of the sense transistor portion 170.

The resistance value Rgs of the sense gate resistor 59 may be equal to or greater than 200 times the resistance value of the off path 160. In this example, the resistance value Rgs of the sense gate resistor 59 may be equal to or greater than 200 times the resistance value Roff of the sense-off resistor 164. The resistance value Rgs is set as described in FIGS. 1 to 7. The sense-off resistor 164 may be the parasitic resistance in the off path 160. In another example, the sense-off resistor 164 may be the resistive element provided in the off path 160. The resistance value Roff may be the same value as the resistance value Rgm. The resistance value Roff may be a value smaller than the resistance value Rgm. The resistance value Roff may be 10 Ω or less.

In this example, by providing the relatively large sense gate resistor 59, it is possible to delay turn-on timing of the sense transistor portion 170, and by providing the relatively small sense-off resistor 164, it is possible to advance turn-off timing. For this reason, it is possible to suppress occurrence of a state in which the main transistor portion 70 is off and the sense transistor portion 170 is on, and it is possible to suppress occurrence of the surge in the sense transistor portion 170.

The resistance value Rgs of the sense gate resistor 59 may be equal to or greater than 2000 times the resistance value of the off path 160. In this example, the resistance value Rgs of the sense gate resistor 59 may be equal to or greater than 2000 times the resistance value Roff of the sense-off resistor 164.

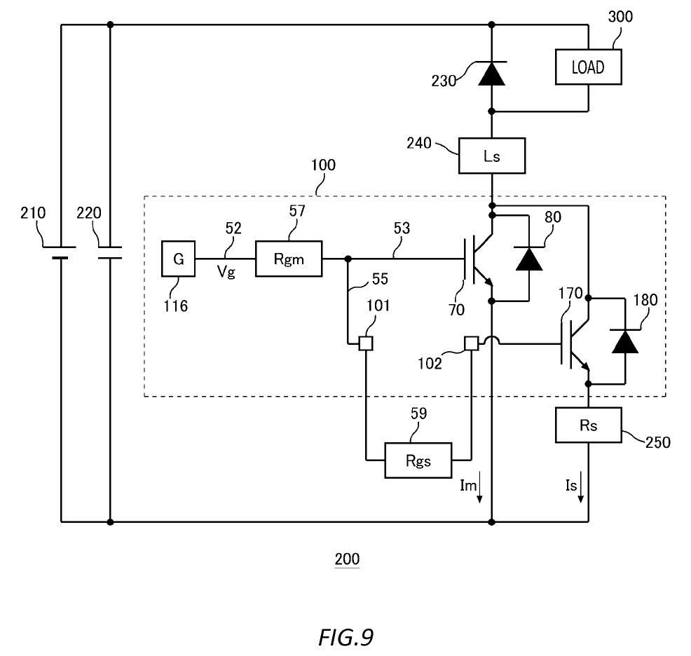

FIG. 9 illustrates another configuration example of the semiconductor device 200. In the semiconductor device 200 illustrated in FIGS. 1 to 8, the sense gate resistor 59 and the sense transistor portion 170 are provided in the same semiconductor chip 100. In the semiconductor device 200 of this example, the sense gate resistor 59 is provided outside the semiconductor chip 100 including the sense transistor portion 170. Other structures are similar to those of the semiconductor device 200 of any example described in FIGS. 1 to 8.

The sense gate transmission portion 55 of the semiconductor chip 100 of this example has the first pad 101 and the second pad 102. The first pad 101 is connected to the gate pad 116. The first pad 101 may be connected to the gate pad 116 by the sense gate transmission portion 55, and may be connected to the gate pad 116 via the main gate transmission portion 53.

The second pad 102 is connected to the gate terminal of the sense transistor portion 170. The second pad 102 may be connected to the sense transistor portion 170 by the sense gate transmission portion 55. The first pad 101 and the second pad 102 are separated from each other inside the semiconductor chip 100. That is, the first pad 101 and the second pad 102 are not connected to each other by wiring of the sense gate transmission portion 55.

The sense gate resistor 59 of this example is connected between the first pad 101 and the second pad 102 outside the semiconductor chip 100. The sense gate resistor 59 may be connected to the first pad 101 and the second pad 102 by wiring such as the wire. The sense gate resistor 59 may be arranged on the circuit board provided in the semiconductor device 200.

Also according to this example, similarly to the examples of FIGS. 1 to 8, occurrence of the surge in the sense transistor portion 170 can be suppressed. In this example, the sense gate resistor 59 selected by the user or the like of the semiconductor device 200 can be mounted on the semiconductor device 200. Therefore, various sense gate resistors 59 can be used for the same type of semiconductor chip 100.

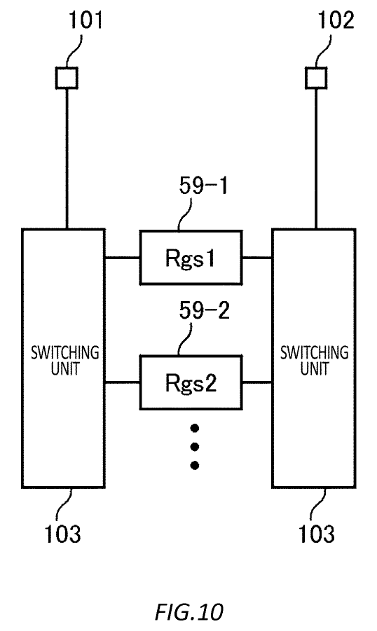

FIG. 10 is a diagram for describing another configuration example of the semiconductor device 200. The semiconductor device 200 of this example differs from the semiconductor device 200 of FIG. 9 in that the semiconductor device 200 of this example includes a plurality of sense gate resistors 59 and the switching unit 103. Other structures are similar to those of the semiconductor device 200 described in FIG. 9. The plurality of sense gate resistors 59 and the switching unit 103 of this example are provided outside the semiconductor chip 100.

The plurality of sense gate resistors 59-1, 59-2, ... may have different resistance values Rgs1, Rgs2, ... from each other. The switching unit 103 switches which of the sense gate resistors 59 is to be connected between the first pad 101 and the second pad 102. Accordingly, the appropriate resistance value Rgs can be selected in accordance with characteristics to be realized.

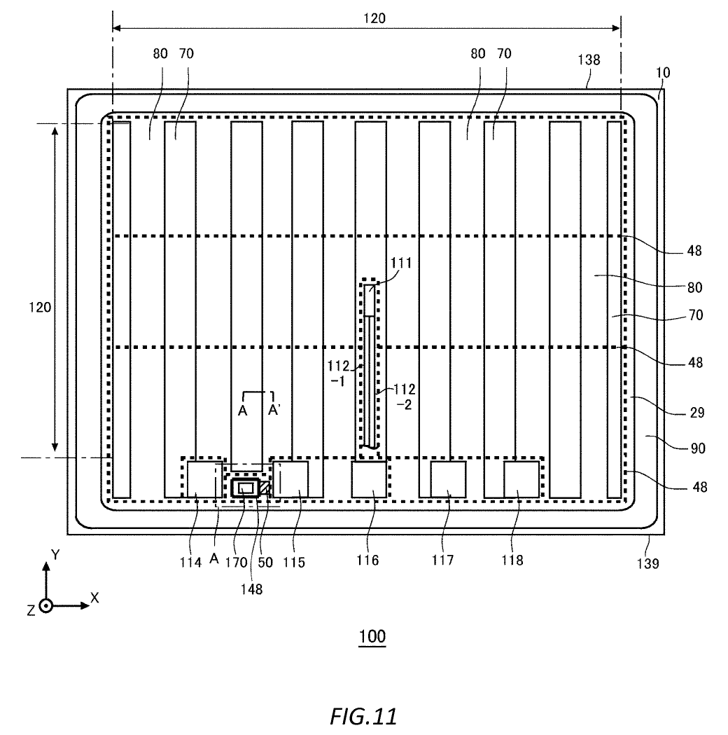

FIG. 11 is a top view illustrating an example of the semiconductor chip 100. FIG. 11 illustrates positions at which respective members are projected on an upper surface of a semiconductor substrate 10. In FIG. 11, only some members of the semiconductor chip 100 are illustrated, and some members are omitted.

The semiconductor chip 100 includes the semiconductor substrate 10. The semiconductor substrate 10 is a substrate formed of a semiconductor material. As an example, the semiconductor substrate 10 is a silicon substrate. Ends of an outer perimeter of the semiconductor substrate 10 when viewed in the top view are referred herein to as outer peripheral ends 138. The phrase "when viewed in the top view" refers to a case where an object is seen in parallel with the Z axis from the upper surface side of the semiconductor substrate 10. In addition, any one end side in the outer peripheral ends 138 of the semiconductor substrate 10 when viewed in the top view is referred to as the first end side 139. A direction parallel to the first end side 139 when viewed in the top view is referred to as an X axis direction, and a direction perpendicular to the first end side 139 is referred to as a Y axis direction.

The semiconductor substrate 10 is provided with the active portion 120. The active portion 120 is the region in which, when the semiconductor chip 100 operates, a main current flows in a depth direction between the upper surface and the lower surface of the semiconductor substrate 10. The active portion 120 may be the region in which the main transistor portion 70 is formed. The main emitter electrode is provided above the active portion 120, but is omitted in FIG. 11.

In the active portion 120, at least one of the main transistor portion 70 including a transistor element such as an IGBT and the diode portion 80 including a diode element such as a freewheeling diode (FWD) is provided. In the example of FIG. 11, the main transistor portion 70 and the diode portion 80 are alternately arranged along the X axis direction. Note that the diode portion 80 may not be provided.

The main transistor portion 70 and the diode portion 80 of the present example each have the longitudinal dimension in the Y axis direction. In other words, the length of each of the main transistor portions 70 in the Y axis direction is larger than the width in the X axis direction. Similarly, the length of each of the diode portions 80 in the Y axis direction is greater than the width in the X axis direction. The longitudinal direction of the main transistor portion 70 and the diode portion 80 and the longitudinal direction of each trench portion described later may be the same.

Each of the diode portions 80 includes a cathode region of an N+ type in a region in contact with the lower surface of the semiconductor substrate 10. In the present specification, a region where the cathode region is provided is referred to as the diode portion 80. In other words, the diode portion 80 is a region that overlaps with the cathode region in the top view. On the lower surface of the semiconductor substrate 10, a collector region of a P+ type may be provided in a region other than the cathode region. In the present specification, the diode portion 80 may also include a region extended from the diode portion 80 to an active well region described later in the Y axis direction. The collector region is provided on a lower surface of the extended region.

Above the upper surface of the semiconductor substrate 10, a plurality of pad portions are provided. In the example of FIG. 11, above the upper surface of the semiconductor substrate 10, the sense pad 114, the auxiliary emitter pad 115, the gate pad 116, the cathode pad 117, and the anode pad 118 are provided.

The sense pad 114 is connected to the sense transistor portion 170. The sense transistor portion 170 has the same structure as the main transistor portion 70, and has a smaller area in the top view (corresponding to the area of the channel) than the main transistor portion 70. By detecting a current flowing through the sense transistor portion 170, a current flowing through the entirety of the semiconductor chip 100 can be estimated.

The auxiliary emitter pad 115 is connected to the main emitter electrode arranged above the upper surface of the semiconductor substrate 10. A wiring line extended from the sense pad 114 may be connected to the main emitter electrode by wire bonding at the auxiliary emitter pad 115 in order to set the wiring line to the same potential as the main emitter electrode.

The gate signal Vg is sent to the gate pad 116 from the gate driver circuit of a control device. The gate pad 116 is connected, via a gate wiring line, to the gate of the main transistor portion 70 and the gate of the sense transistor portion 170.

The cathode pad 117 and the anode pad 118 are connected to the temperature sensing unit 111 via the temperature sense wiring line 112. The temperature sensing unit 111 measures the temperature of the semiconductor chip 100. The temperature sensing unit 111 is, as an example, the diode for temperature measurement. The temperature sense wiring line 112 extends from the temperature sensing unit 111 to the region between the active portion 120 and the outer peripheral end 138 on the upper surface of the semiconductor substrate 10, and is connected to the cathode pad 117 and the anode pad 118. The temperature sense wiring line 112 may be polysilicon. It should be noted that a number and types of pad portions provided to the semiconductor substrate 10 are not limited to those in the example illustrated in FIG. 11.

Each pad portion is formed of a metal material such as aluminum. The plurality of pad portions may be arrayed in a predetermined direction between the active portion 120 and the first end side 139 on the upper surface of the semiconductor substrate 10. The plurality of pad portions of the present example are arrayed in the X axis direction, and are arranged so as to be sandwiched between the active portion 120 and the first end side 139 in the Y axis direction.

In the array direction of the plurality of pad portions, the sense transistor portion 170 may be provided between any two pad portions. The sense transistor portion 170 of the present example is arranged between the sense pad 114 and the auxiliary emitter pad 115 in the X axis direction.

The sense transistor portion 170 has a sense gate trench portion having a trench structure, as will be described later. The sense gate trench portion has a sense gate conductive portion to which a gate voltage is applied. As will be described later, the main transistor portion 70 also has the gate trench portion having a trench structure. The gate trench portion has the gate conductive portion to which a gate voltage is applied.

The semiconductor substrate 10 has the gate wiring 48 and the sense gate wiring 148. The main gate wiring 48 is an example of the main gate transmission portion 53. The sense gate wiring 148 is an example of the sense gate transmission portion 55. The main gate wiring 48 is provided on an upper surface of the semiconductor substrate 10 and surrounds the active portion 120 and at least one of the plurality of pad portions. The main gate wiring 48 is also provided so as to cross the active portion 120. The main gate wiring 48 is connected to the gate conductive portion of the main transistor portion 70. That is, the main gate wiring 48 extends from the gate pad 116 to the gate conductive portion.

The main gate wiring 48 is wiring that transmits the gate signal Vg to the gate conductive portion. The main gate wiring 48 may be wiring through which a charging current for charging the gate conductive portion flows. The main gate wiring 48 may be gate wiring other than the sense gate wiring 148 to be described later. In FIG. 11, the gate wiring 48 is illustrated with dotted lines.

The sense gate wiring 148 is provided above the upper surface of the semiconductor substrate 10 and is arranged along the sense transistor portion 170. The sense gate wiring 148 of the present example surrounds the sense transistor portion 170. The sense gate wiring 148 is connected to the sense gate conductive portion of the sense transistor portion 170. Being arranged along the sense transistor portion 170 may refer to being arranged in parallel with any one side of the sense transistor portion 170. The distance between the sense gate wiring 148 and the sense transistor portion 170 may be smaller than the distance between the sense transistor portion 170 and the sense pad 114. For example, when the sense transistor portion 170 is rectangular, the sense gate wiring 148 may be arranged in parallel with two or more sides of the sense transistor portion 170, and may be arranged in parallel with three or more sides. When there are a plurality of gate wirings arranged in parallel with any one side of the sense transistor portion 170, the sense gate wiring 148 may refer to the gate wiring closest to the sense transistor portion 170.

The sense gate wiring 148 is wiring that transmits the gate signal to the sense gate conductive portion. The sense gate wiring 148 may be, among the wiring through which a charging current for charging the sense gate conductive portion flows, wiring arranged along the outer shape of the sense transistor portion 170. The sense gate wiring 148 need not include wiring through which the charging current for charging the gate conductive portion flows.

In FIG. 11, the sense gate wiring 148 is illustrated with bold solid lines. The sense gate wiring 148 of the present example is arranged in a closed loop surrounding the sense transistor portion 170. The main gate wiring 48 and the sense gate wiring 148 may each have, at least in part, a stacked structure of metal and polysilicon. An insulating film may be provided between the metal wiring and the polysilicon wiring. The metal wiring and the polysilicon wiring may be electrically connected via the contact hole provided in the insulating film. The main gate wiring 48 and the sense gate wiring 148 are insulated from the upper surface of the semiconductor substrate 10 by the interlayer dielectric film.

The semiconductor substrate 10 has the gate wiring connection portion 50 that connects the gate wiring 48 and the sense gate wiring 148. The gate wiring connection portion 50 of this example is arranged between the sense transistor portion 170 and the auxiliary emitter pad 115. The gate wiring connection portion 50 is wiring that transmits the gate signal Vg to the sense gate conductive portion, and is wiring through which the charging current for charging the sense gate conductive portion flows.

The gate wiring connection portion 50 may function as the sense gate resistor 59. The gate wiring connection portion 50 may be the wiring formed of polysilicon. In the gate wiring connection portion 50, the resistance value Rgs of the gate wiring connection portion 50 can be adjusted by adjusting the cross-sectional area perpendicular to the direction in which the gate current flows. Also, the resistance value Rgs of the gate wiring connection portion 50 can be adjusted by adjusting the length of the gate wiring connection portion 50 in the direction in which the gate current flows. Also, the resistance value Rgs can be adjusted by adjusting the concentration of an impurity added to the polysilicon of the gate wiring connection portion 50. The gate wiring connection portion 50 may be high-resistance wiring formed of the high-resistance material other than polysilicon.

Instead of the gate wiring connection portion 50, the first pad 101 and the second pad 102 described in FIG. 9 and the like may be provided. The first pad 101 is connected to the main gate wiring 48, and the second pad 102 is connected to the sense gate wiring 148.

The semiconductor substrate 10 includes the active main well region 29 formed so as to surround the active portion 120 in the top view. The active main well region 29 surrounds the main transistor portion 70 and the diode portion 80 in the top view. The active main well region 29 is the second conductivity type region provided inside from the upper surface of the semiconductor substrate 10. The active main well region 29 may surround the active portion 120 along the main gate wiring 48. The active main well region 29 is also provided in the periphery of the pad portion, but illustration of the periphery of the pad portion is omitted in FIG. 11.

An edge termination structure portion 90 is provided between the active well region and the outer peripheral end 138 of the semiconductor substrate 10 at the upper surface of the semiconductor substrate 10. The edge termination structure portion 90 may be circularly arranged so as to surround the active well region at the upper surface of the semiconductor substrate 10. The edge termination structure portion 90 of the present example is arranged along the outer peripheral ends 138 of the semiconductor substrate 10. The edge termination structure portion 90 reduces an electric field strength on the upper surface side of the semiconductor substrate 10. The edge termination structure portion 90 includes, for example, a guard ring, a field plate, a RESURF and a combination structure of them.

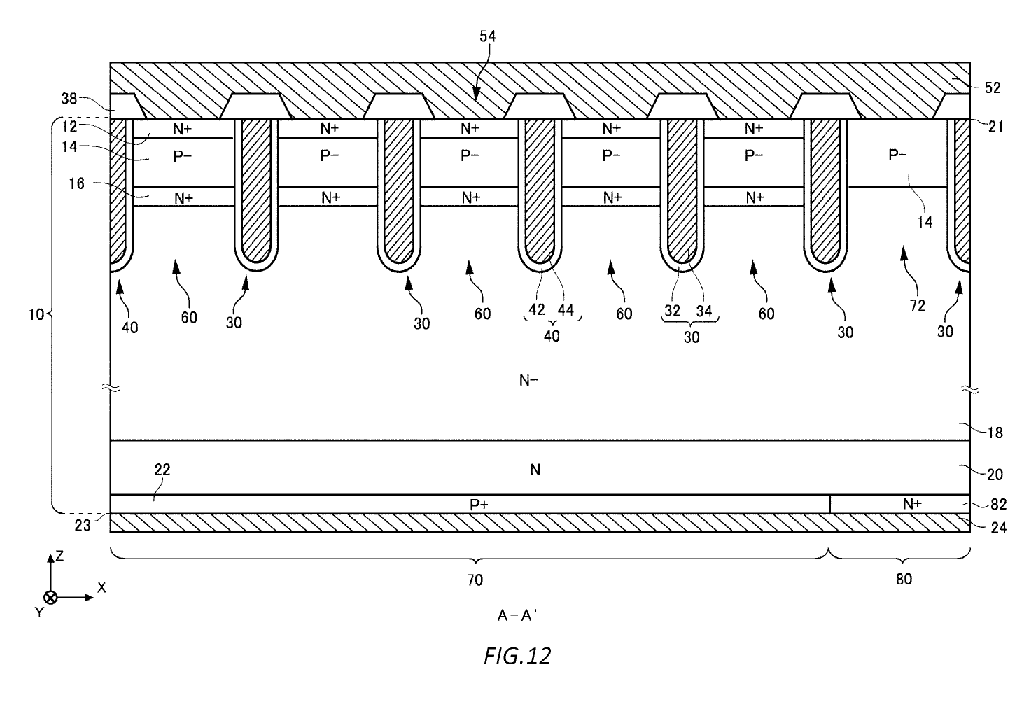

FIG. 12 illustrates an example of an A-A’ cross section in FIG. 11. The A-A' cross section is the XZ cross section passing through the emitter region 12 of the main transistor portion 70 and the diode portion 80. The sense transistor portion 170 may also have the structure illustrated in FIG. 12. However, the main transistor portion 70 and the sense transistor portion 170 may be separated by the P+ type well region. The well region is P+ having a higher concentration than the base region 14, and is formed from the upper surface 21 of the semiconductor substrate 10 to a position deeper than the lower end of the gate trench portion 40. The well region may be provided so as to surround the sense transistor portion 170 in the top view.

In the A-A' cross section, the semiconductor chip 100 includes the semiconductor substrate 10, the collector electrode 24, the interlayer dielectric film 38, and the main emitter electrode 52. The semiconductor substrate 10 has the upper surface 21 and the lower surface 23. The upper surface 21 and the lower surface 23 are two principal surfaces of the semiconductor substrate 10.

The interlayer dielectric film 38 is provided on the upper surface 21 of the semiconductor substrate 10. The main emitter electrode 52 is provided above the interlayer dielectric film 38. The main emitter electrode 52 is in contact with the upper surface 21 of the semiconductor substrate 10 through the contact hole 54 of the interlayer dielectric film 38. The collector electrode 24 is provided on the lower surface 23 of the semiconductor substrate 10. The main emitter electrode 52 and the collector electrode 24 are formed of the metal material such as aluminum.

The main transistor portion 70 and the diode portion 80 have the drift region 18 of a first conductivity type and the base region 14 of a second conductivity type that is provided between the drift region 18 and the upper surface 21 of the semiconductor substrate 10. The drift region 18 of this example is of an N- type, and the base region 14 is of a P- type.

In the main transistor portion 70, a plurality of the gate trench portions 40 and a plurality of the dummy trench portions 30 are provided toward the inside from the upper surface 21 of the semiconductor substrate 10. The gate trench portions 40 and the dummy trench portions 30 of this example are arrayed along the X axis direction and have the longitudinal direction in the Y axis direction. The gate trench portion 40 has a trench, the gate dielectric film 42, and the gate conductive portion 44. The gate dielectric film 42 is provided covering an inner wall of the trench. The gate dielectric film 42 may be formed by oxidizing or nitriding a semiconductor on the inner wall of the trench. The gate conductive portion 44 is provided inside the gate dielectric film 42 inside the trench. In other words, the gate dielectric film 42 insulates the gate conductive portion 44 from the semiconductor substrate 10. The gate conductive portion 44 is formed of a conductive material such as polysilicon.

The dummy trench portion 30 has a trench, the dummy insulating film 32, and the dummy conductive portion 34. The structure of the dummy trench portion 30 may be similar to that of the gate trench portion 40. However, the gate conductive portion 44 is connected to the main gate wiring 48, whereas the dummy trench portion 30 need not be connected to the main gate wiring 48. The dummy conductive portion 34 may be connected to the main emitter electrode 52 in a cross section different from the A-A' cross section. The diode portion 80 also has a plurality of dummy trench portions 30.

The main transistor portion 70 has the mesa portion 60, which is the region between the gate trench portion 40 and the dummy trench portion 30. Similarly, the diode portion 80 has the mesa portion 72, which is the region between the dummy trench portions 30. Each mesa portion is provided with the base region 14.

The main transistor portion 70 has the emitter region 12 of a first conductivity type provided on the upper surface 21. The emitter region 12 is exposed on the upper surface 21 of the semiconductor substrate 10, and is provided in contact with the gate trench portion 40 or the dummy trench portion 30. The emitter region 12 may be in contact with the gate trench portions 40 or the dummy trench portions 30 on both sides of the mesa portion 60.

The base region 14 is provided below the emitter region 12. The base region 14 in this example is provided in contact with the emitter region 12. The base region 14 may be in contact with the gate trench portions 40 or the dummy trench portions 30 on both sides of the mesa portion 60.

The accumulation region 16 is provided below the base region 14. The accumulation region 16 is a region of the N+ type having a higher doping concentration than the drift region 18. Providing the accumulation region 16 having a high concentration between the drift region 18 and the base region 14 can increase a carrier injection enhancement effect (IE effect) and reduce an on-voltage. The accumulation region 16 may be provided so as to cover the entire lower surface of the base region 14 in each mesa portion 60.

The mesa portion 72 of the diode portion 80 is provided with the base region 14 of the P- type in contact with the upper surface 21 of the semiconductor substrate 10. The drift region 18 is provided below the base region 14. In the mesa portion 72 of the diode portion 80, the emitter region 12 is not provided.

The main transistor portion 70 has the collector region 22 of the second conductivity type provided on the lower surface 23 of the semiconductor substrate 10. The collector region 22 in the present example is of the P+ type. An acceptor concentration of the collector region 22 is higher than an acceptor concentration of the base region 14. The collector region 22 may include an acceptor which is the same as or different from an acceptor of the base region 14. The acceptor of the collector region 22 is, for example, boron.

The diode portion 80 includes a cathode region 82 of the first conductivity type provided on the lower surface 23 of the semiconductor substrate 10. The cathode region 82 in the present example is of the N+ type. A donor concentration of the cathode region 82 is higher than a donor concentration of the drift region 18. A donor of the cathode region 82 is, for example, hydrogen or phosphorous. Note that an element serving as a donor and an acceptor in each region is not limited to the example described above.

The collector region 22 and the cathode region 82 are exposed on the lower surface 23 of the semiconductor substrate 10 and are connected to the collector electrode 24. The collector electrode 24 may be in contact with the entire lower surface 23 of the semiconductor substrate 10.

The main transistor portion 70 may be the region in which the collector region 22 is provided on the lower surface 23. The diode portion 80 may be the region in which the cathode region 82 is provided on the lower surface 23. The boundary between the main transistor portion 70 and the diode portion 80 may be the boundary between the cathode region 82 and the collector region 22.

The buffer region 20 of the N+ type may be provided between the drift region 18, and the collector region 22 and the cathode region 82. The doping concentration in the buffer region 20 is higher than the doping concentration in the drift region 18. The buffer region 20 may function as a field stopper layer which prevents a depletion layer expanding from a lower end of the base region 14 from reaching a collector region 22 of the P+ type.

In a cross section different from the A-A' cross section, a contact region of the second conductivity type may be provided in the main transistor portion 70 and the diode portion 80. The contact region may be provided between the base region 14 and the upper surface 21. The contact region may be a region of the P+ type having a higher doping concentration than the base region 14.

The gate trench portion 40 and the dummy trench portion 30 reach, from the upper surface 21 of the semiconductor substrate 10 and passing through the base region 14, the drift region 18. In the region in which at least one of the emitter region 12, the contact region, and the accumulation region 16 is provided, the gate trench portion 40 and the dummy trench portion 30 also pass through these doping regions and reach the drift region 18. The configuration of the trench portion passing through the doping region is not limited to one manufactured in the order of forming the doping region and then forming the trench portion. The configuration of the trench portions passing through the doping region also includes a configuration of forming the trench portions and then forming the doping region between the trench portions. It should be noted that a bottom portion of the trench portion may have a curved-surface shape (a curved-line shape in the cross section) protruding downward.

The gate conductive portion 44 may be provided longer than the base region 14 in the depth direction. The gate trench portion 40 is covered with the interlayer dielectric film 38 on the upper surface 21 of the semiconductor substrate 10. The gate conductive portion 44 is electrically connected to the main gate wiring 48. When a predetermined gate voltage is applied to the gate conductive portion 44, a channel is formed by an electron inversion layer in a surface layer of the base region 14 at a boundary in contact with the gate trench portion 40. Accordingly, in the main transistor portion 70, a main current flows between the main emitter electrode 52 and the collector electrode 24.

As described above, when a predetermined gate voltage is applied to the gate conductive portion of each transistor portion, carriers are injected from the collector region 22. Self-charging occurs by the carriers being charged in the gate dielectric film 42 of the gate trench portion 40, and the transistor portion is self-turned on. The gate dielectric film 42 of the sense transistor portion 170 can also be charged by carriers injected from the collector region 22 of the main transistor portion 70 in the periphery. Similarly, the gate dielectric film 42 of the main transistor portion 70 can also be charged by carriers injected from the collector region 22 of the sense transistor portion 170 in the periphery. However, the area of the sense transistor portion 170 is much smaller than the area of the main transistor portion 70. Therefore, the sense transistor portion 170 is greatly affected by carriers from the main transistor portion 70, and is more likely to be self-turned on earlier than the main transistor portion 70.

As described above, according to the semiconductor device 200, the turn-on timing of the sense transistor portion 170 can be delayed. Accordingly, occurrence of a surge in the sense transistor portion 170 can be suppressed.

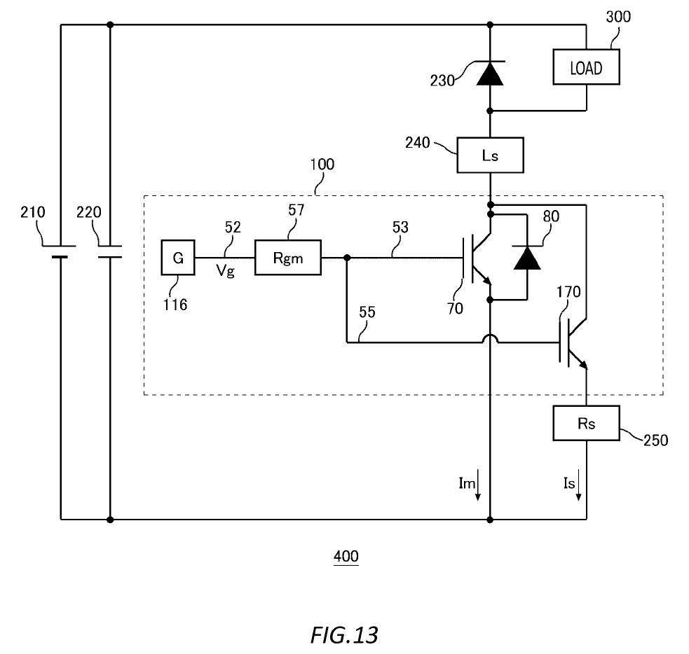

FIG. 13 illustrates an example of the semiconductor device 400 according to a comparative example. The semiconductor device 400 does not have the sense gate resistor 59, and the sense transistor portion 170 is not an RC-IGBT. In the structure of the semiconductor device 400, the ESD withstand capability (withstand capability against electrostatic discharge) of the sense transistor portion 170 is low.

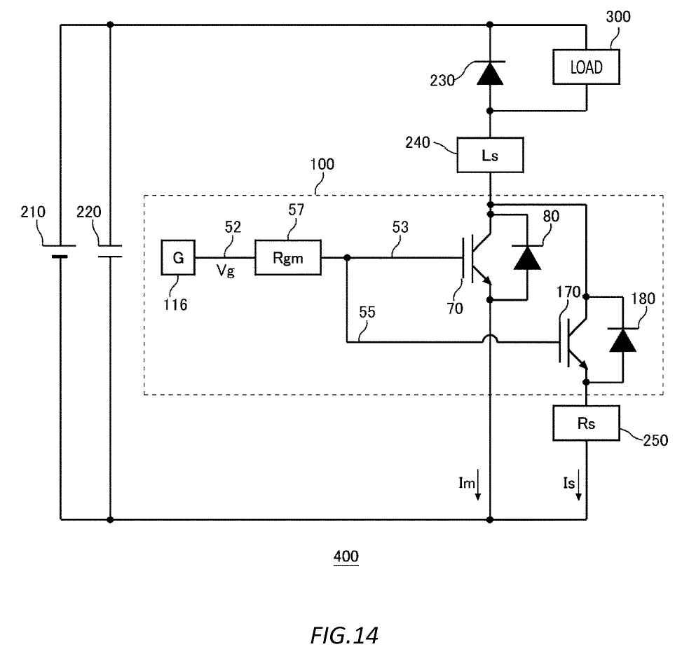

FIG. 14 illustrates another example of the semiconductor device 400 according to a comparative example. The semiconductor device 400 of this example does not have the sense gate resistor 59. However, the sense transistor portion 170 is an RC-IGBT. With such a configuration, the S-E withstand capability can be improved. The S-E withstand capability is a withstand capability between the sense pad 114 and the main emitter electrode 52. On the other hand, the S-G withstand capability has not been improved. The S-G withstand capability is a withstand capability between the sense pad 114 and the gate pad 116. In contrast, according to the semiconductor device 200 described in FIG. 1 and the like, by providing the relatively large sense gate resistor 59, the S-G withstand capability can also be improved.

While the present invention has been described by way of the embodiments, the technical scope of the present invention is not limited to the above-described embodiments. It is apparent to persons skilled in the art that various alterations or improvements can be added to the above-described embodiments. It is also apparent from the described scope of the claims that the embodiments added with such alterations or improvements can be included the technical scope of the present invention.

What is claimed is:

1. A semiconductor device comprising:
a main transistor portion that causes a main current to flow in accordance with an applied gate signal; and
a sense transistor portion that is provided in parallel with the main transistor portion and causes a sense current to flow in accordance with the gate signal common to the main transistor portion,
wherein a gate resistance ratio obtained by dividing a resistance value of a sense gate resistor, which is a gate drive resistor of the sense transistor portion, by a resistance value of a main gate resistor, which is a gate drive resistor of the main transistor portion, is equal to or greater than 0.015 times a current ratio obtained by dividing the main current by the sense current.

2. The semiconductor device according to claim 1, wherein
the gate resistance ratio is equal to or greater than 0.5 times the current ratio.

3. The semiconductor device according to claim 1, wherein
the gate resistance ratio is equal to or greater than 1 time the current ratio.

4. The semiconductor device according to claim 1, wherein
the gate resistance ratio is equal to or less than 2.5 times the current ratio.

5. The semiconductor device according to claim 1, wherein
the gate resistance ratio is 30 or more.

6. The semiconductor device according to claim 1, wherein
the gate resistance ratio is 1000 or more.

7. The semiconductor device according to claim 1, wherein
the gate resistance ratio is 2000 or more.

8. The semiconductor device according to claim 5, wherein
the gate resistance ratio is 5000 or less.

9. The semiconductor device according to claim 6, wherein
the gate resistance ratio is 5000 or less.

10. The semiconductor device according to claim 1, wherein
a resistance value of the sense gate resistor is 300 Ω or more.

11. The semiconductor device according to claim 1, wherein
a resistance value of the sense gate resistor is 10 kΩ or more.

12. The semiconductor device according to claim 1, wherein
a resistance value of the sense gate resistor is 20 kΩ or more.

13. The semiconductor device according to claim 10, wherein a resistance value of the sense gate resistor is 50 kΩ or less.

14. The semiconductor device according to claim 1, further comprising:
a main gate transmission portion that transmits the gate signal to the main transistor portion; and
a sense gate transmission portion that is provided in parallel with the main gate transmission portion and transmits the gate signal to the sense transistor portion,
wherein the sense gate transmission portion includes:
an on path that has the sense gate resistor and causes a gate current to flow to a gate terminal of the sense transistor portion in accordance with the gate signal; and
an off path that is provided in parallel with the on path and extracts charge from the gate terminal of the sense transistor portion in accordance with the gate signal, and
wherein a resistance value of the sense gate resistor is equal to or greater than 200 times a resistance value of the off path.

15. The semiconductor device according to claim 14, wherein
a resistance value of the sense gate resistor is equal to or greater than 2000 times a resistance value of the off path.

16. The semiconductor device according to claim 14, wherein the on path includes:
a first diode having a cathode terminal connected to the gate terminal of the sense transistor portion; and
the sense gate resistor provided in series with the first diode,
the off path includes:
a second diode having an anode terminal connected to the gate terminal of the sense transistor portion; and
a sense-off resistor provided in series with the second diode, and
a resistance value of the sense gate resistor is equal to or greater than 200 times a resistance value of the sense-off resistor.

17. The semiconductor device according to claim 1, wherein
the sense gate resistor and the sense transistor portion are provided on a same semiconductor chip.

18. The semiconductor device according to claim 1, wherein
the sense gate resistor is provided outside a semiconductor chip including the sense transistor portion.

19. The semiconductor device according to claim 18, further comprising:
a gate pad to which the gate signal is applied; and
a sense gate transmission portion that transmits the gate signal to the sense transistor portion,
wherein the sense gate transmission portion includes:
a first pad connected to the gate pad; and
a second pad connected to the sense transistor portion, and
the sense gate resistor is connected between the first pad and the second pad.

20. The semiconductor device according to claim 19, comprising:
a plurality of sense gate resistors; and
a switching unit that switches which of the sense gate resistors is to be connected between the first pad and the second pad.
